(19) United States
(12) Patent Application Publication
(10) Pub. No.: US 2023/0189480 A1
(43) Pub. Date: Jun. 15, 2023

(54) ELECTRONIC DEVICE

(71) Applicant: FANUC CORPORATION, Minamitsuru-gun (JP)

(72) Inventors: Wataru KUROKI, Minamitsuru-gun, Yamanashi-ken (JP); Shinichi HORIKOSHI, Minamitsuru-gun, Yamanashi-ken (JP)

(21) Appl. No.: 17/925,933

(22) PCT Filed: May 14, 2021
(86) PCT No.: PCT/JP2021/018318

§ 371 Date: Nov. 17, 2022

(30) Foreign Application Priority Data
May 20, 2020 (JP) 2020-088123

(51) Int. Cl. H05K 7/20; H05K 1/18; H05K 1/02

(52) U.S. Cl. CPC H05K 7/2039; H05K 1/18; H05K 1/0203; H05K 2201/105

(57) ABSTRACT

In an electronic device, a stay is fixed to a surface of a heatsink on the side of a substrate or to a side surface of the heatsink, and is also fixed to the substrate. A contact portion of the stay which is in contact with the heatsink is in contact with the heatsink by mating therewith. The electron device is further provided with a fastening member for fixing the contact potion to the heatsink in detachable manner.

### TECHNICAL FIELD

The present invention relates to an electronic device equipped with a substrate, a heat-generating component fixed to the substrate, a radiator that is provided on an opposite side of the heat-generating component from the substrate, and that dissipates heat from the heat-generating component, and a stay by which the radiator is installed on the substrate.

### BACKGROUND ART

Conventionally, in an electronic device in which a heat-generating component such as a power device is fixed to a substrate, and a radiator for dissipating heat from the heat-generating component is provided on an opposite side of the heat-generating component from the substrate, the radiator is fixed to the substrate via stays. In this case, the heat-generating component and the stays are fixed to the substrate, for example, by soldering, and are fixed to the radiator by screws.

In this instance, when the heat-generating component is replaced, the substrate is detached from the heat-generating component and the stays in a state in which all of the solder is melted, and thereafter, the screws are loosened and the heat-generating component is detached from the radiator. Therefore, the replacement operation becomes complicated. Instead of such a replacement operation, it may be considered to detach the heat-generating component from the substrate by loosening the screws and thereby detaching the radiator from the heat-generating component and the stays, and melting only the solder of the heat-generating component.

Moreover, in JP 2016-178132 A, a control device (electronic device) is disclosed in which a radiator is fixed to a substrate by bolts.

### SUMMARY OF THE INVENTION

However, when the stays are fixed to the heat-radiator by the screws, there is a possibility that the stays may rotate about a fastening point of the screws when the screws are turned. Therefore, a fixture for preventing the stays from rotating is required.

Further, even in the case that the stays are fixed to the radiator by the screws, the stays may rotate about the fastening point of the screws prior to the stays being fixed to the substrate by solder or the like as a result of forces being applied to the stays by vibrations, impacts or the like during transportation. Therefore, it is necessary to fix the contact portions where the stays are in contact with the radiator by a plurality of screws, in a manner so that the stays do not rotate.

Thus, an object of the present invention is to provide an electronic device in which rotation of stays when the stays are fixed to the radiator can be prevented without using a fixture for preventing such rotation, and the number of the fastening members such as screws for fixing the stays to the radiator can be reduced.

An aspect of the present invention is characterized by an electronic device including: a substrate; a heat-generating component fixed to one surface of the substrate; a radiator provided on an opposite side of the heat-generating component from the substrate and configured to dissipate heat from the heat-generating component; and a stay configured to install the radiator on the substrate. In this case, the stay is fixed to a surface of the radiator on a side of the substrate, or to a side surface of the radiator, and is fixed to the substrate. Further, a contact portion of the stay where the stay is in contact with the radiator is fitted into and placed in contact with the radiator. In addition, the electronic device further includes a fastening member configured to detachably fix the contact portion to the radiator.

According to the present invention, since the contact portions of the stays with the radiator are fitted into and placed in contact with the radiator, rotation of the stays when the stays are fixed to the radiator can be prevented without using a fixture for preventing such rotation, and the number of the fastening members such as screws for fixing the stays to the radiator can be reduced.

### BRIEF DESCRIPTION OF DRAWINGS

FIG. 1 is a side view of an electronic device according to an embodiment of the present invention;

FIG. 2 is a bottom view showing a state in which a substrate is detached from the electronic device shown in FIG. 1;

FIG. 3 is a cross-sectional view taken along line in FIG. 1;

FIG. 4 is a side view of an electronic device according to a comparative example;

FIG. 5 is a bottom view showing a state in which a substrate is detached from the electronic device shown in FIG. 4;

FIG. 6 is a side view of an electronic device according to a first exemplary modification;

FIG. 7 is a cross-sectional view taken along line VII-VII in FIG. 6;

FIG. 8 is a side view of an electronic device according to a second exemplary modification;

FIG. 9 is a bottom view showing a state, in an electronic device according to a third exemplary modification, in which a substrate is detached from the electronic device;

FIG. 10 is a side view of an electronic device according to a fourth exemplary modification;

FIG. 11 is a side view of an electronic device according to a fifth exemplary modification;

FIG. 12 is a cross-sectional view taken along line XII-XII in FIG. 11;

FIG, 13 is a side view of an electronic device according to a sixth exemplary modification;

FIG. 14 is a side view of an electronic device according to a seventh exemplary modification; and

FIG. 15 is a side view of an electronic device according to an eighth exemplary modification,

### DESCRIPTION OF THE INVENTION

A preferred embodiment of an electronic device according to the present invention will be presented and described in detail below with reference to the accompanying drawings.

### 1. Embodiment

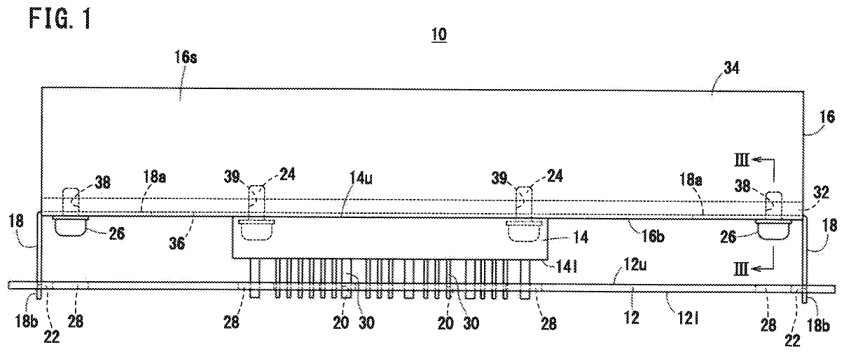

FIG. 1 is a side view of an electronic device 10 according to an embodiment of the present invention.

The electronic device 10 is equipped with a substrate 12, a heat-generating component 14 fixed to one surface (an upper surface 12u) of the substrate 12, a radiator 16 provided on an opposite side (an upper surface 14u) of the heat-generating component 14 from the substrate 12 and configured to dissipate heat from the heat-generating component 14, and stays 18 that serve to install the radiator 16 on the substrate 12.

The substrate 12, for example, is a printed circuit board, and a non-illustrated circuit pattern is formed in the interior of the substrate 12 which is made up from an electrical insulating material, and on one surface (the upper surface 12u) and another surface (a bottom surface 12l) of the substrate 12. Further, a plurality of through holes 20 and 22 through which various terminals and the like are inserted are formed vertically in the substrate 12. Furthermore, in the substrate 12, through holes 28 through which a tool such as a screwdriver can be inserted are formed in a vertical direction at locations directly below a plurality of screws 24 and 26, which will be described later.

The heat-generating component 14, for example, is a power device such as an intelligent power module (IPM) or an insulated gate bipolar transistor (IGBT). The heat-generating component 14 generates heat when driven by electrical power supplied from a non-illustrated power supply. Further, a plurality of pin-shaped terminals 30 are provided on a bottom surface 141 of the heat-generating component 14 on the substrate 12 side. The heat-generating component 14 is fixed to the upper surface 12u of the substrate 12 by the plurality of terminals 30 and the circuit pattern being joined together by soldering, in a state in which the plurality of terminals 30 are inserted through the plurality of through holes 20. Further, the heat-generating component 14 is detachably fixed by two screws 24 to the surface (a bottom surface 16b) of the radiator 16 on the substrate 12 side, so as to be in surface contact therewith.

The plurality of stays 18 are fixed to the surface (the bottom surface 16b) of the radiator 16 on the substrate 12 side, and in addition, to the substrate 12. Specifically, the plurality of stays 18 are substantially L-shaped metal plate members. One end part 18a (contact portion) of each of the stays 18 are detachably fixed to the bottom surface 16b of the radiator 16 by a single screw 26 in a state of being in surface contact with the bottom surface 16b of the radiator 16. Further, another end part 18b of each of the stays 18 is formed in a pin shape, and is fixed to the substrate 12 by being joined to the circuit pattern by soldering in a state of being inserted through the through hole 22. It should be noted that, in the embodiment shown in FIGS. 1 to 3, a case is illustrated in which four stays 18 are provided.

The radiator 16, for example, is a heat sink, and is constituted by a flat plate-shaped base 32 provided on the substrate 12 side, and a plurality of fins 34 provided on an opposite side of the base 32 from the substrate 12 and extending upwardly so as to separate away from the substrate 12. Moreover, in the following description, the term the “bottom surface 16b of the radiator 16” may also be referred to as the “bottom surface 16b of the base 32”.

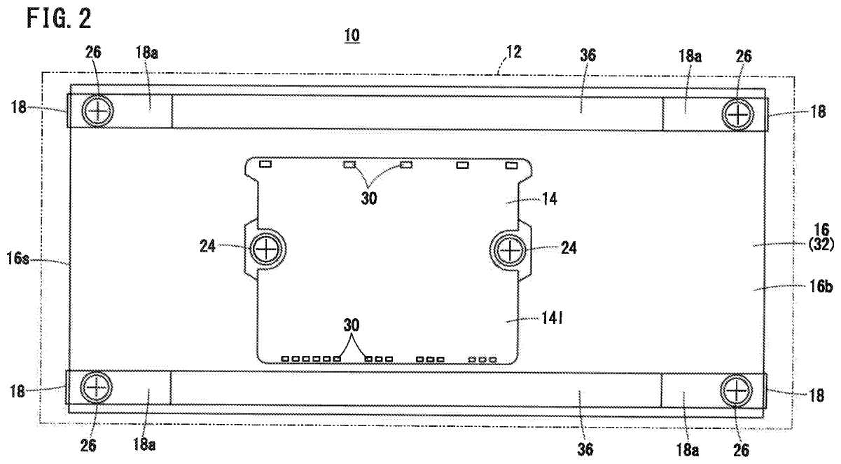

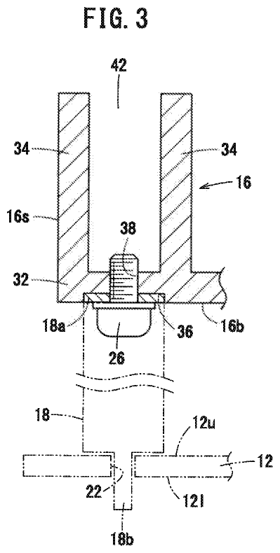

Two fitting grooves 36 are formed in the bottom surface 16b of the base 32. The one end parts 18a of the four stays 18 are fitted into the two fitting grooves 36. More specifically, the two fitting grooves 36 are formed to have a width and depth that allow the one end parts 18a of the four stays 18 to be fitted thereinto. Accordingly, by the one end parts 18a thereof being fitted into the fitting grooves 36, the four stays 18 are placed in surface contact with the bottom surface 16b of the base 32, in a state in which the one end parts 18a are roughly positioned in the width direction of the fitting grooves 36 (see FIGS. 2 and 3). In this state, the one end parts 18a of the four stays 18 are fixed inside the fitting grooves 36 by one screw 26 each, respectively.

In the case of assembling the electronic device 10 which is configured in such a manner, at first, the one end parts 18a of the stays 18 are fitted into the fitting grooves 36, and the one end parts 18a of the stays 18 and the fitting grooves 36 are placed in surface contact. As a result, the one end parts 18a of the stays 18 are roughly positioned in the width direction of the fitting grooves 36.

Next, one screw 26 is used to fix each of the one end parts 18a of the stays 18 to a predetermined position on the bottom surface 16b of the radiator 16 (the base 32). In this case, the one end part 18a of the stay 18 is positioned in the width direction of the fitting groove 36. Therefore, in the case that the screw 26 is turned and screwed into a screw hole 38 formed on the bottom surface 16b side of the base 32, it is possible to restrict the stay 18 from being rotated at a predetermined angle (an angle defined between the one end part 18a and the fitting groove 36) or greater about the fastening point of the screw 26.

Moreover, as noted previously, the electronic device 10 is equipped with the four stays 18. Therefore, the same operations are performed on the remaining three stays 18.

Next, the heat-generating component 14 is fixed to the bottom surface 16b of the base 32, by screw-engagement of the two screws 24 into two screw holes 39 that are formed in a central portion on the bottom surface 16b side of the base 32. Next, the plurality of terminals 30 of the heat-generating component 14 and the other end parts 18b of the four stays 18 are inserted through the plurality of through holes 20 and 22 of the substrate 12. Thereafter, the plurality of terminals 30 and the other end parts 18b of the stays 18 are joined to the circuit pattern of the substrate 12 by soldering. Consequently, the heat-generating component 14 and the other end parts 18b of the stays 18 are fixed to the substrate 12.

On the other hand, when the heat-generating component 14 is replaced, the following operations are performed. First, a tool such as a screwdriver is inserted through the plurality of through holes 28, and the plurality of screws 24 and 26 are loosened using the tool. Consequently, the plurality of screws 24 and 26 are taken out from the radiator 16, and the four stays 18 and the heat-generating component 14 can be separated away from the radiator 16 in the vertical direction. Next, the heat-generating component 14 is detached from the substrate 12 by melting only the solder that joins the plurality of terminals 30 of the heat-generating component 14 and the circuit pattern. Thus, it is possible to replace the heat-generating component 14.

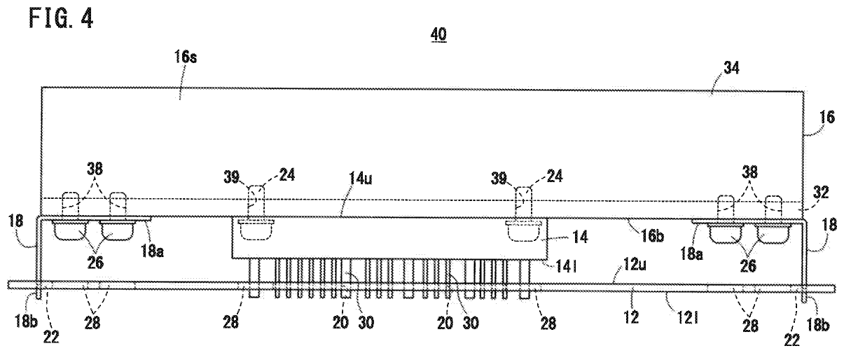

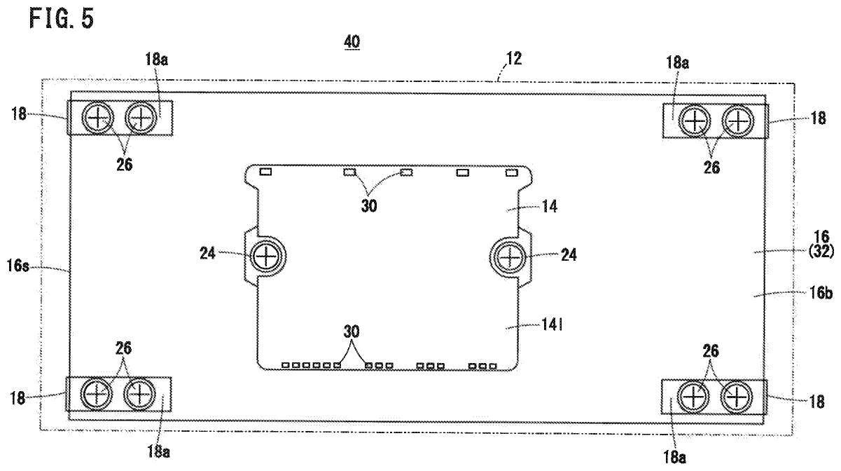

FIG. 4 is a side view of an electronic device 40 according to a comparative example, and FIG. 5 is a bottom view showing a state in which the substrate 12 is detached from the electronic device 40. In FIGS. 4 and 5, the same constituent elements as those of the electronic device 10 according to the embodiment shown in FIGS. 1 to 3 are denoted and described by the same reference numerals.

In the electronic device 40 of the comparative example, the fitting grooves 36 are not formed in the bottom surface 16b of the base 32. Accordingly, the four stays 18 are each fixed to the bottom surface 16b of the base 32 by two screws 26. More specifically, in the electronic device 40 according to the comparative example, if one screw 26 were used to fix the one end part 18a of the stay 18 to the radiator 16, and the stay 18 were fixed to the substrate 12, vibration and impact during transportation could be applied to the stay 18, thereby leading to a possibility of the stay 18 rotating about the fastening point of the one screw 26. Thus, in the comparative example, the one end part 18a of the stay 18 is fixed with two screws 26, in a manner so that the stay 18 does not rotate. Consequently, the number of the screws 26 increases, and the operation of assembling the electronic device 40, as well as the operation of replacing the heat-generating component 14 become complicated.

In contrast thereto, in the electronic device 10 according to the embodiment, as described above, the one end part 18a of each of the stays 18 is fitted into the fitting groove 36, and in a state of being in surface contact with the bottom surface 16b of the base 32, the one end part 18a of the stay 18 is fixed to the bottom surface 16b of the base 32 by one screw 26. Consequently, the number of the screws 26 for fixing the one end parts 18a of the stays 18 to the bottom surface 16b of the base 32 can be reduced.

Further, by the one end parts 18a of the stays 18 being fitted into the fitting grooves 36, the one end parts 18a of the stays 18 are positioned in the width direction of the fitting grooves 36. As a result, when the one end part 18a of each of the stays 18 is fixed to the bottom surface 16b of the base 32 by one screw 26, the stay 18 can be prevented from rotating about the fastening point of the screw 26.

In this manner, with the electronic device 10 of the embodiment, the operation of assembling the electronic device 10, and the operation of replacing the heat-generating component 14 can be carried out easily and efficiently. Further, when the one end parts 18a of the stays 18 are fixed to the bottom surface 16b of the base 32, rotation of the stays 18 can be prevented without using a fixture for preventing the rotation.

### 2. Exemplary Modifications

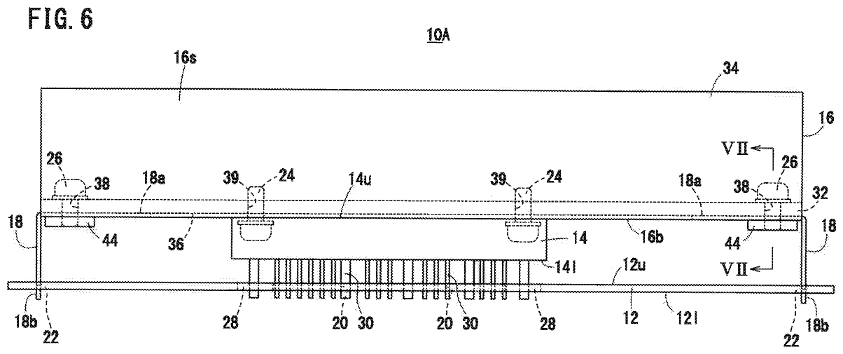

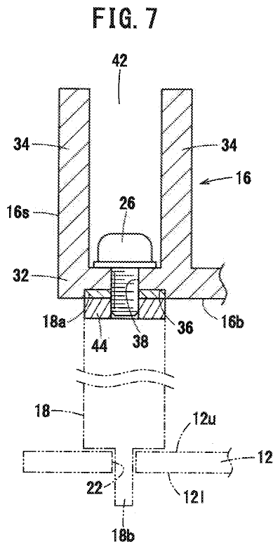

Next, exemplary modifications (first to eighth exemplary modifications) of the electronic device 10 according to the embodiment shown in FIGS. 1 to 3 will be described with reference to FIGS. 6 to 15. Moreover, in the first to eighth exemplary modifications, the same reference numerals are used to designate the same configurations as those of the electronic device 10 according to the embodiment, and detailed description of such configurations will be omitted.

### 2.1 First Exemplary Modification

An electronic device 10A according to the first exemplary modification differs in that, as shown in FIGS, 6 and 7, the fastening direction of the screws 26 that fix the one end parts 18a of the stays 18 to the radiator 16 is opposite to that of the screws 26 in the electronic device 10 according to the embodiment (see FIGS. 1 to 3). in this case, the fitting grooves 36 are provided at locations on the bottom surface 16b of the base 32 where gaps 42 between the two fins 34 are projected. Further, the through holes 28 corresponding to the screws 26 are not provided in the substrate 12.

In addition, in the first exemplary modification, in the case that the one end parts 18a of the stays 18 are fixed to the bottom surface 16b of the base 32, at first, the one end parts 18a of the stays 18 are fitted into the fitting grooves 36. Consequently, the one end parts 18a of the stays 18 are positioned in the width direction of the fitting grooves 36 in a state of being in surface contact with the bottom surface 16b of the base 32. Next, the screws 26 are inserted into the screw holes 38 through the gaps 42, and the screws 26 are turned using a tool such as a screwdriver. The screws 26 are screw-engaged with nuts 44 that are arranged on the bottom surface side of the one end parts 18a of the stays 18. Consequently, the one end parts 18a of the stays 18 are fixed to the bottom surface 16b of the base 32.

In this manner, in the electronic device 10A according to the first exemplary modification, the fastening direction of the screws 26 is opposite to that of the electronic device 10 of the embodiment. Therefore, the effects similar to those of the electronic device 10 of the embodiment can be obtained.

### 2.2 Second Exemplary Modification

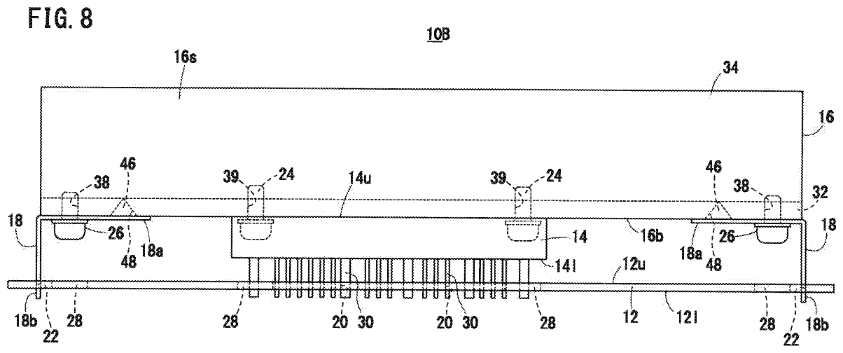

In an electronic device 10B according to the second exemplary modification, as shown in FIG. 8, the fitting grooves 36 are not formed. In the second exemplary modification, projecting parts 46 are formed on the surface (the upper surface) of the one end parts 18a of the stays 18 on the base 32 side. Further, concave parts 48 are provided on the bottom surface 16b of the base 32 correspondingly to the projecting parts 46. The one end parts 18a of the stays 18 are placed in surface contact with the bottom surface 16b of the base 32, by the projecting parts 46 and the concave parts 48 being fitted together. By turning one screw 26 in this state, each of the one end parts 18a of the stays 18 is fixed to the bottom surface 16b of the base 32.

In this case, if a direction in which the projecting part 46 projects is an upward direction, and the cross-sectional shape of the surface (the horizontal surface) of the projecting part 46 perpendicular to the projecting direction is a polygonal or elliptical shape, one projecting part 46 is provided for one stay 18. On the other hand, the bottom surface 16b of the base 32 is provided with one concave part 48 whose surface (horizontal surface) perpendicular to a concave direction (the upward direction) has a polygonal or elliptical cross-sectional shape. Consequently, by the projecting parts 46 and the concave parts 48 being fitted together, the one end parts 18a of the stays 18 can be positioned in surface contact with respect to the bottom surface 16b of the base 32. As a result, when the one end parts 18a of the stays 18 are fixed by the screws 26 to the bottom surface 16b of the base 32, the stays 18 can be effectively prevented from rotating about the screws 26.

Further, in the case that the cross-sectional shape of the surface perpendicular to the projecting direction is a circular shape, a plurality of the projecting parts 46 are provided for one stay 18. On the other hand, the bottom surface 16b of the base 32 is provided with a plurality of the concave parts 48 whose surfaces perpendicular to the concave direction have a circular cross-sectional shape. Consequently, by the plurality of projecting parts 46 and the plurality of concave parts 48 being fitted together, the one end parts 18a of the stays 18 can be positioned in surface contact with respect to the bottom surface 16b of the base 32. In this case as well, when the one end parts 18a of the stays 18 are fixed by the screws 26 to the bottom surface 16b of the base 32, the stays 18 can be effectively prevented from rotating about the screws 26.

Accordingly, in the second exemplary modification as well, the effects similar to those of the electronic device 10 of the embodiment can be obtained.

Moreover, in the second exemplary modification, the projecting parts 46 may be provided on the bottom surface 16b of the base 32, and the concave parts 48 may be provided on the one end parts 18a of the stays 18. Also in such a case, the aforementioned effects can be obtained. In the case that the projecting parts 46 are provided on the bottom surface 16b of the base 32, because an ordinary dowel forming process is difficult to perform, the projecting parts 46 may be formed, for example, by using a metal additive manufacturing technique in which a 3D printer is used.

### 2.3 Third Exemplary Modification

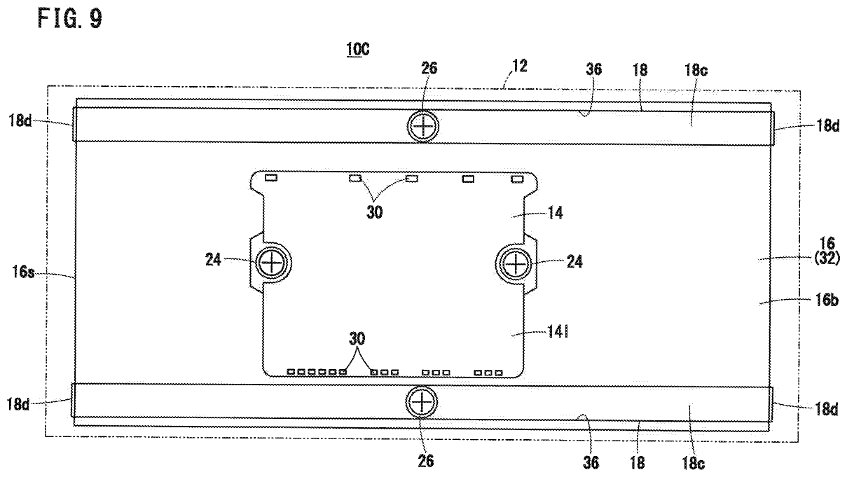

As shown in FIG. 9, an electronic device 10e according to the third exemplary modification differs from the electronic device 10 according to the embodiment (see FIGS. 1 to 3), in that central portions 18c of the stays 18 are fitted into the fitting grooves 36, and both end parts 18d of the stays 18 are fixed to the substrate 12. Moreover, the both end parts 18d are fixed to the substrate 12 in the same manner as the other end parts 18b.

In this case, one stay 18 is fitted into one fitting groove 36. Further, the central portion 18c of one stay 18 is fitted into the fitting groove 36, and in a state of being in surface contact with the bottom surface 16b of the base 32, the central portion 18c of the stay 18 is fixed to the bottom surface 16b of the base 32 by one screw 26.

According to the third exemplary modification, in comparison with the embodiment, the first exemplary modification, and the second exemplary modification (see FIGS. 1 to 3 and FIGS. 6 to 8), the overall length of the stays 18 becomes longer, and the cost of the stays 18 becomes higher, while on the other hand, the number of the screws 26 can be reduced. It should be noted that the number of the screws 26 used for one stay 18 can be increased from one to two.

### 2.4 Fourth Exemplary Modification

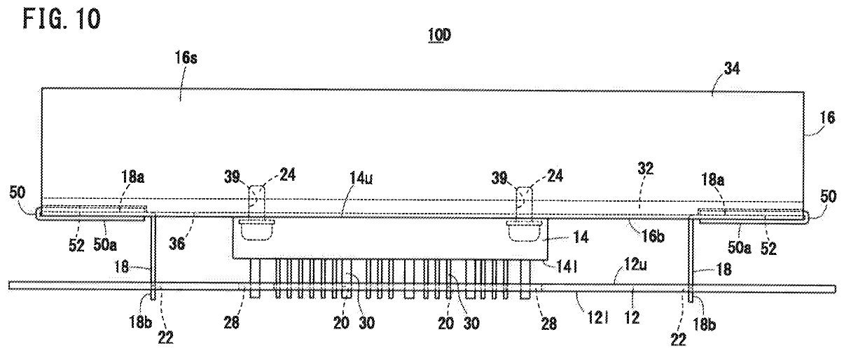

In an electronic device 10D according to the fourth exemplary modification, as shown in FIG. 10, by the one end parts 18a of the stays 18 being gripped by clips 50 (fastening members) provided on the radiator 16, the one end parts 18a of the stays 18 are fixed to the bottom surface 16b of the base 32 in a state of being fitted into the fitting grooves 36. Accordingly, the fourth exemplary modification differs from the embodiment (see FIGS. 1 to 3), and the first to third exemplary modifications (see FIGS. 6 to 9), in that the screws 26 for fixing the one end parts 18a of the stays 18 to the bottom surface 16b of the base 32 are not provided.

In this case, both end parts of each of the fitting grooves 36 are formed as deeper accommodation grooves 52, and two clips 50 are arranged in two accommodation grooves 52. The two clips 50 are arranged in a manner so that claw-shaped gripping parts 50a thereof that sandwich the one end parts 18a of the stays 18 therein face toward each other.

In this instance, when the one end parts 18a of the two stays 18 are fitted into the central portion of the fitting groove 36, the one end parts 18a of the stays 18 and the fitting groove 36 are fitted together, and the one end parts 18a of the stays 18 are positioned in the width direction of the fitting groove 36. In this state, when the one end parts 18a of the two stays 18 are made to slide toward the both end parts of the fitting groove 36, the one end parts 18a of the stays 18 are inserted into the gripping parts 50a of the clips 50, and are retained by an elastic force. As a result, the one end parts 18a of the two stays 18 are fixed to the bottom surface 16b of the base 32.

In the foregoing manner, in the electronic device 10D according to the fourth exemplary modification, the fixture for preventing rotation, and the screws 26 for fixing the one end parts 18a of the stays 18 can be rendered unnecessary. Further, the one end parts 18a of the stays 18 are gripped by the elastic force of the clips 50, and therefore, when the other end parts 18b of the stays 18 are fixed to the substrate 12, rotation of the stays 18 can be effectively prevented.

It should be noted that the clips 50 are not limited to having the shape shown in FIG. 10. The clips 50 may have any kind of structure, as long as they are capable of gripping the one end parts 18a of the stays 18 by means of an elastic force. For example, instead of the clips 50 having a U-shaped cross section shown in FIG. 10, the clips 50 having an Ω-shaped cross section may be adopted.

### 2.5 Fifth Exemplary Modification

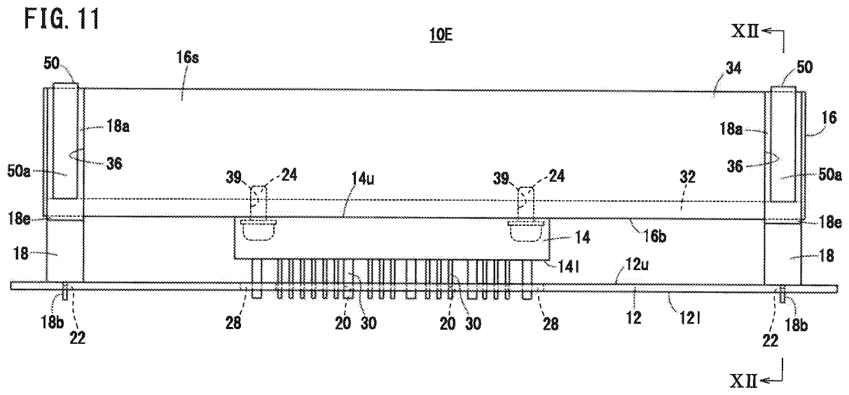

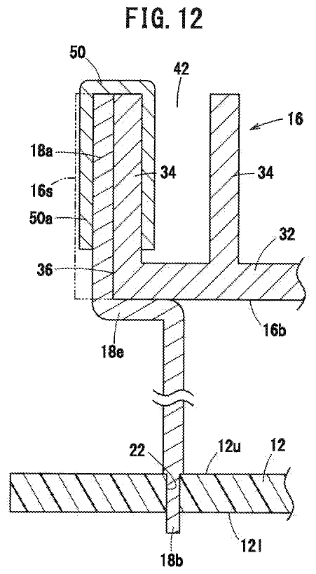

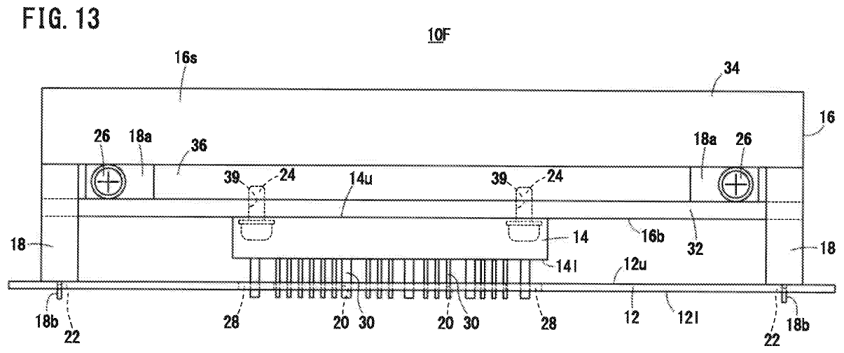

In an electronic device 10E according to the fifth exemplary modification, as shown in FIGS. 11 and 12, the fitting grooves 36 are formed along a vertical direction in a side surface 16s of the radiator 16, and the one end parts 18a of the stays 18 are fitted into the fitting grooves 36. In this case, the stays 18 extend upwardly from the other end parts 18b, and are bent and extend further upwardly in an L-shape. Bent portions 18e that connect the one end parts 18a and the other end parts 18b of the stays 18 are placed in surface contact with the bottom surface 16b of the base 32. Further, in the same manner as in the fourth exemplary modification (see FIG. 10), the one end parts 18a of the stays 18 that are fitted into the fitting grooves 36 are gripped by the clips 50 provided on the upper side of the fitting grooves 36.

As shown in FIG. 12, the clips 50 each sandwich therein the one end part 18a of the stay 18 and the fin 34 in which the fitting groove 36 is formed. More specifically, in a state of being fitted into the lower end part of the fitting groove 36, when the one end part 18a of the stay 18 is made to slide toward the upper end part of the fitting groove 36, the one end part 18a of the stay 18 is inserted into the gripping part 50a of the clip 50. The clips 50 grip by an elastic force the one end parts 18a of the stays 18 and the fins 34 in which the fitting grooves 36 are formed, and fix the one end parts 18a of the stays 18 in the fitting grooves 36.

In the electronic device 10E according to the fifth exemplary modification as well, the effects similar to those of the fourth exemplary modification can be obtained. Moreover, in FIGS. 11 and 12, although the bent portions 18e are provided on the stays 18 in order to support the radiator 16, the above-described effects can be obtained even in the case that the stays 18 extending straight in the vertical direction are adopted.

### 2.6 Sixth Exemplary Modification

In an electronic device IOF according to the sixth exemplary modification, as shown in FIG. 13, the fitting grooves 36 are formed along a horizontal direction in the side surface 16s of the radiator 16, and the one end parts 18a of the stays 18 are fitted into the fitting grooves 36. In this case as well, the one end parts 18a of the stays 18 are fitted into the fitting grooves 36, and in a state of being in surface contact with the side surface 16s of the radiator 16, the one end parts 18a of the stays 18 can be fixed by the screws 26 to the side surface 16s of the radiator 16. Accordingly, in the sixth exemplary modification as well, the effects similar to those of the embodiment can be obtained.

### 2.7 Seventh Exemplary Modification

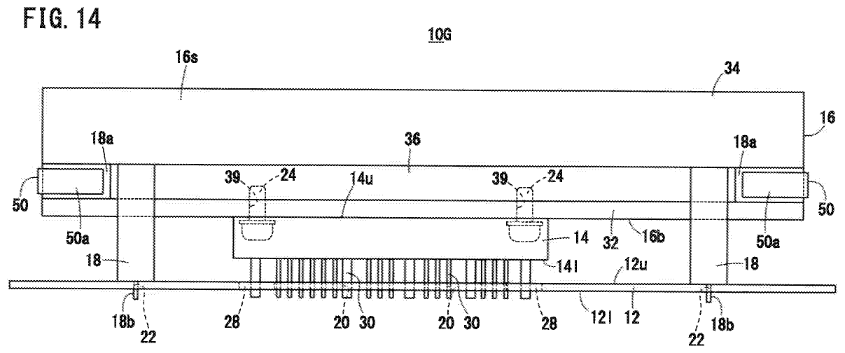

In an electronic device 10G according to the seventh exemplary modification, as shown in FIG. 14, the fitting grooves 36 are formed along a horizontal direction in the side surface 16s of the radiator 16, and the clips 50 are arranged respectively on both end parts of the fitting grooves 36. In this case as well, in the same manner as in the fourth and fifth exemplary modifications (see FIGS. 10 to 12), the one end parts 18a of the stays 18 are fitted into the fitting grooves 36, and in a state of being in surface contact with the side surface 16s of the radiator 16, the one end parts 18a of the stays 18 can be fixed by the clips 50 to the side surface 16s of the radiator 16. Accordingly, in the seventh exemplary modification as well, the effects similar to those of the fourth exemplary modification and the fifth exemplary modification can be obtained.

### 2.8 Eighth Exemplary Modification

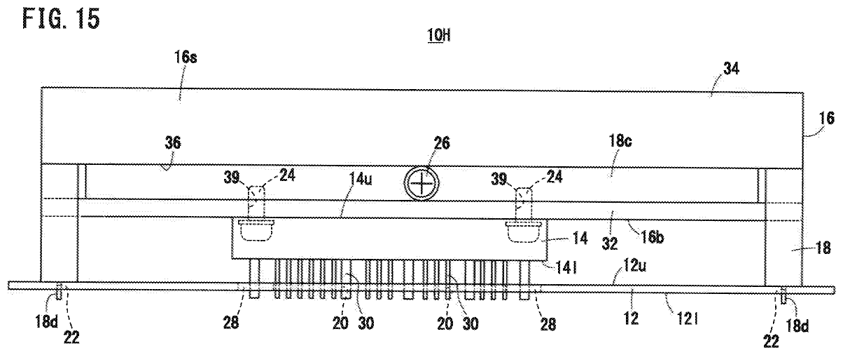

In an electronic device 10H according to the eighth exemplary modification, as shown in FIG. 15, the fitting grooves 36 are formed along a horizontal direction in the side surface 16s of the radiator 16, and the central portions 18c of the stays 18 are fitted into the fitting grooves 36. In this case as well, in the same manner as in the third exemplary modification (see FIG. 9), the central portions 18c of the stays 18 are fitted into the fitting grooves 36, and in a state of being in surface contact with the side surface 16s of the radiator 16, the central portions 18c of the stays 18 can be fixed by the screws 26 to the side surface 16s of the radiator 16. Accordingly, in the eighth exemplary modification as well, the effects similar to those of the third exemplary modification can be obtained.

### Other Exemplary Modifications

In the above-described embodiment and the first to eighth exemplary modifications, cases have been described in which the screws 26 or the clips 50 are used as fastening members for fixing the stays 18 to the radiator 16. Instead of the screws 26 or the clips 50, rivets may be used for fixing the stays 18 to the radiator 16.

Further, concerning the clips 50 as well, in order to enhance resistance to vibration, such clips may be clips 50 having an elastic force such that they cannot be easily removed manually and can be removed only by means of a tool. Furthermore, the clips 50 and the rivets may be made of a metal or a resin. For example, various types of clips and rivets such as scrivets, trim clips, push-turn rivets, plastic rivets, canoe clips, and anchor clips can be preferably used as the fastening members for fixing the stays 18 to the radiator 16.

Furthermore, concerning the fixing portions where the stays 18 are fixed to the substrate 12, instead of being joined by soldering, the stays 18 may be fixed to the substrate 12 using the various types of rivets and clips described above.

### Inventions that can be Obtained from the Embodiment

The inventions that can be grasped from the above-described embodiment and the modifications thereof will be described below.

The electronic device (10, 10A to 10H) is equipped with the substrate (12), the heat-generating component (14) which is fixed to the one surface (12u) of the substrate (12), the radiator (16) provided on the opposite side (14u) of the heat-generating component (14) from the substrate (12) and configured to dissipate heat from the heat-generating component (14), and the stays (18) for installing the radiator (16) on the substrate (12), wherein the stays (18) are fixed to the surface (16b) of the radiator (16) on the substrate (12) side, or to the side surface (16s) of the radiator (16), and are fixed to the substrate (12), the contact portions (18a, 18c) of the stays (18) where the stays (18) are in contact with the radiator (16) are fitted into and placed in contact with the radiator (16), and the electronic device is further equipped with the fastening members (26, 50) for detachably fixing the contact portions (18a, 18c) to the radiator (16).

In the foregoing manner, since the contact portions (18a, 18c) of the stays (18) with the radiator (16) are fitted into and placed in contact with the radiator (16), rotation of the stays (18) when fixed to the radiator can be prevented without using a fixture for preventing such rotation, and the number of the fastening members (26, 50) such as screws for fixing the stays (18) to the radiator (16) can be reduced.

The radiator (16) includes the fitting grooves (36), and the contact portions (18a, 18c) are fitted into the fitting grooves (36). In accordance with this feature, the contact portions (18a, 18c) and the radiator (16) can be easily fitted together and brought into contact with each other.

The contact portions (18a) are the one end parts (18a) of the stays (18), and the other end parts (18b) of the stays (18) are fixed to the substrate (12). In accordance with this feature, the radiator (16) can be easily supported on the substrate (12) via the stays (18).

The contact portions (18c) are the central portions (18c) of the stays (18), and the both end parts (18d) of the stays (18) are fixed to the substrate (12). Since the length of the stays (18) is made longer, the cost of the stays (18) increases, however, the stays (18) can be reliably fitted into the fitting grooves (36).

The projecting parts (46) are provided on the one of the contact portions (18a, 18c) or the radiator (16), and the concave parts (48) are provided on the other thereof, and the projecting parts (46) and the concave parts (48) are fitted together. In this case as well, by the projecting parts (46) and the concave parts (48) being fitted together, a fixture for preventing rotation can be rendered unnecessary, and the number of the fastening members (26, 50) such as screws for fixing the stays (18) to the radiator (16) can be reduced.

One projecting part (46) whose surface perpendicular to the projecting direction thereof has a polygonal or elliptical cross-sectional shape is provided on one of the contact portions (18a, 18c) or the radiator (16), and one concave part (48) whose surface perpendicular to the concave direction thereof has a polygonal or elliptical cross-sectional shape is provided on the other thereof. In accordance with this feature, it is possible to prevent rotation of the stays (18) while reliably positioning the contact portions (18a, 18c) of the stays (18) with respect to the radiator (16).

The plurality of projecting parts (46) whose surfaces perpendicular to the projecting direction thereof have a circular cross-sectional shape are provided on one of the contact portions (18a, 18c) or the radiator (16), and the plurality of concave parts (48) whose surfaces perpendicular to the concave direction thereof have a circular cross-sectional shape are provided on the other thereof, and the plurality of projecting parts (46) and the plurality of concave parts (48) are fitted together. In this case as well, it is possible to prevent rotation of the stays (18) while reliably positioning the contact portions (18a, 18c) of the stays (18) with respect to the radiator (16).

The fastening members (26, 50) are the screws (26), the rivets, or the clips (50). In accordance with this feature, the stays (18) can be easily fixed to the radiator (16) at a low cost.

The heat-generating component (14) is detachably fixed to the radiator (16). In accordance with this feature, it is possible to easily attach and detach the heat-generating component (14) to and from the radiator (16).

The heat-generating component (14) is joined to the substrate (12) by soldering, and the fixing portions (18b, 18d) of the stays (18) where the stays (18) are fixed to the substrate (12) are joined to the substrate (12) by soldering. In accordance with this feature, the heat-generating component (14) and the stays (18) can be fixed to the substrate (12) in the same configuration as in the conventional art.

1. An electronic device comprising: a substrate; a heat-generating component fixed to one surface of the substrate; a radiator provided on an opposite side of the heat-generating component from the substrate and configured to dissipate heat from the heat-generating component; and a stay configured to install the radiator on the substrate,
wherein the stay is fixed to a surface of the radiator on a side of the substrate, or to a side surface of the radiator, and is fixed to the substrate,
a contact portion of the stay where the stay is in contact with the radiator is fitted into and placed in contact with the radiator, and
the electronic device further comprises a fastening member configured to detachably fix the contact portion to the radiator.

2. The electronic device according to claim 1, wherein
the radiator includes a fitting groove, and
the contact portion is fitted into the fitting groove.

3. The electronic device according to claim 2, wherein
the contact portion is one end part of the stay, and
another end part of the stay is fixed to the substrate.

4. The electronic device according to claim 2, wherein
the contact portion is a central portion of the stay, and
both end parts of the stay are fixed to the substrate.

5. The electronic device according to claim 1, wherein
a projecting part is provided on one of the contact portion or the radiator, and a concave part is provided on another one of the contact portion or the radiator, and
the projecting part and the concave part are fitted together.

6. The electronic device according to claim 5, wherein
the projecting part whose surface perpendicular to a projecting direction thereof has a polygonal or elliptical cross-sectional shape is provided on one of the contact portion or the radiator, and the concave part whose surface perpendicular to a concave direction thereof has a polygonal or elliptical cross-sectional shape is provided on another one of the contact portion or the radiator.

7. The electronic device according to claim 5, wherein a plurality of the projecting parts whose surfaces perpendicular to a projecting direction thereof have a circular cross-sectional shape are provided on one of the contact portion or the radiator, and a plurality of the concave parts whose surfaces perpendicular to a concave direction thereof have a circular cross-sectional shape are provided on another one of the contact portion or the radiator, and
the plurality of projecting parts and the plurality of concave parts are fitted together.

8. The electronic device according to claim 1, wherein
the fastening member is a screw, a rivet, or a clip.

9. The electronic device according to claim 1, wherein
the heat-generating component is detachably fixed to the radiator.

10. The electronic device according to claim 1, wherein
the heat-generating component is joined to the substrate by soldering, and
a fixing portion of the stay where the stay is fixed to the substrate is joined to the substrate by soldering.
